(19) United States
(12) Patent Application Publication
(10) Pub. No.: US 2024/0287385 A1
(43) Pub. Date: Aug. 29, 2024

(54) ETCHING COMPOSITION FOR SEMICONDUCTOR SUBSTRATE FOR MEMORY ELEMENT AND METHOD FOR MANUFACTURING SEMICONDUCTOR SUBSTRATE FOR MEMORY ELEMENT USING SAME

(71) Applicant: MITSUBISHI GAS CHEMICAL COMPANY, INC., Tokyo (JP)

(72) Inventors: Toshiyuki OIE, Taichung City (TW); Tomoyuki ADANIYA, Tokyo (JP); Chih-Liang YANG, Taichung City (TW); Po-Hung WANG, Taichung City (TW)

(73) Assignee: MITSUBISHI GAS CHEMICAL COMPANY, INC., Tokyo (JP)

(21) Appl. No.: 18/573,719

(22) PCT Filed: Jun. 29, 2022
(86) PCT No.: PCT/JP2022/025880

§ 371 Date: Dec. 22, 2023

(30) Foreign Application Priority Data
Jul. 2, 2021 (JP) 2021-110798

(51) Int. Cl. C09K 13/08; H01L 29/49; H10B 12/00

(52) U.S. Cl. CPC C09K 13/08; H01L 29/495; H10B 12/02; H10B 12/488

(57) ABSTRACT

Provided is an etching composition for a semiconductor substrate for a memory element capable of providing a semiconductor substrate for a memory element having improved performance. The etching composition for a semiconductor substrate for a memory element comprises: (A) an oxidizing agent; (B) a fluorine compound; and (C) a metal tungsten corrosion inhibitor, wherein (C) the metal tungsten corrosion inhibitor contains at least one selected from the group consisting of an ammonium salt represented by formula (1) and a heteroaryl salt having a C14-C30 alkyl group.

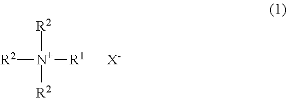

### TECHNICAL FIELD

The present invention relates to an etching composition for a semiconductor substrate for a memory element and a method for producing a semiconductor substrate for a memory element using the same.

### BACKGROUND ART

In recent years, further size reduction and advanced features have been required for memory elements, and technologies for miniaturization, three-dimensional integration, etc. of semiconductor substrates have been developed.

For semiconductor substrates that can realize size reduction and advanced features of memory elements, metal tungsten is suitably used as a material thereof. A film of metal tungsten can be formed by CVD (chemical vapor deposition), and has characteristics such as lower susceptibility to electromigration, low electrical resistance and high heat resistance. For this reason, metal tungsten is used for embedded word lines or the like in memory elements such as DRAM.

It is known that the aforementioned embedded word lines can be produced, for example, by the following method. That is, a silicon dioxide film, a titanium-containing film (barrier film) that contains titanium and/or a titanium alloy, and a metal tungsten film are sequentially formed on a silicon substrate having a recess formed by etching. Subsequently, the surface thereof is flattened by CMP (chemical mechanical polishing), and further the titanium-containing film and the metal tungsten film, or the metal tungsten film is selectively etched by dry etching or the like (CMP may be omitted). After that, the titanium-containing film is selectively etched to produce embedded word lines in memory elements (Non-Patent Document 1).

Thus, the method for producing a semiconductor substrate for a memory element includes a step of selectively removing titanium and/or a titanium alloy without damaging metal tungsten (titanium and/or a titanium alloy selective etching step). For this reason, when metal tungsten is used to produce a small-sized and high-performance memory element, there is a demand for an etching composition by which titanium and/or a titanium alloy is etched without etching metal tungsten (having high Ti/W etching selectivity).

### PRIOR ART DOCUMENTS

### Non-Patent Documents

Non-Patent Document 1: SPCC 2019 Technical Program, “Wet Etchant for DRAM Word-line Titanium Nitride Recess with Selectivity to Tungsten”, Wilson et al., [https://www.linx-consulting.com/wp-content/uploads/2019/04/03-15-W_Yeh-Dupont-Wet_Etchant_for_DRAM_Word_line_TiN_Recess_with_Selectivity_to_W.pdf]

### SUMMARY OF THE INVENTION

### Problems to be Solved by the Invention

However, it was found that there are cases where a memory element having desired performance cannot be obtained by using a conventional etching composition in an attempt to produce a semiconductor substrate for a memory element in which metal tungsten is used as a material.

Therefore, the present invention provides an etching composition capable of providing a semiconductor substrate for a memory element having improved performance.

### Means for Solving the Problems

The present invention provides, for example, etching compositions described below.

[1] An etching composition for a semiconductor substrate for a memory element, comprising an oxidizing agent (A), a fluorine compound (B), and a metal tungsten corrosion inhibiter (C),
wherein the metal tungsten corrosion inhibiter (C) contains at least one selected from the group consisting of an ammonium salt represented by formula (1) and a heteroaryl salt having a substituted or unsubstituted alkyl group having 14 to 30 carbon atoms:

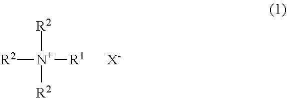

wherein in formula (1):
R¹ represents a substituted or unsubstituted alkyl group having 14 to 30 carbon atoms, a substituted or unsubstituted alkyl(poly)heteroalkylene group having 14 to 30 carbon atoms, or a substituted or unsubstituted aryl(poly)heteroalkylene group having 14 to 30 carbon atoms;
each R² independently represents a substituted or unsubstituted alkyl group having 1 to 30 carbon atoms, or a substituted or unsubstituted aryl group having 6 to 30 carbon atoms; and
X represents a halide ion, a hydroxide ion, an organic sulfonate ion, a tetrafluoroborate anion, or a hexafluorophosphate anion.
   [2] The etching composition for a semiconductor substrate for a memory element according to item [1], wherein said R¹ represents a substituted or unsubstituted alkyl(poly)heteroalkylene group having 14 to 30 carbon atoms, or a substituted or unsubstituted aryl(poly)heteroalkylene group having 14 to 30 carbon atoms.
   [3] The etching composition for a semiconductor substrate for a memory element according to item [2], wherein said R¹ represents a substituted or unsubstituted aryl(poly)heteroalkylene group having 14 to 20 carbon atoms.
   [4] The etching composition for a semiconductor substrate for a memory element according to any one of items [1] to [3], which has a surface tension of 50 mN/m or less.
   [5] The etching composition for a semiconductor substrate for a memory element according to any one of items [1] to [4], which further comprises a pH adjuster (D).
   [6] The etching composition for a semiconductor substrate for a memory element according to any one of items [1] to [5], which has a pH ranging from 0.1 to 5.0.
   [7] The etching composition for a semiconductor substrate for a memory element according to any one of items [1] to [6], which further comprises an organic solvent (E).
   [8] The etching composition for a semiconductor substrate for a memory element according to item [7], wherein the organic solvent (E) is an alcohol.
   [9] A method for producing a semiconductor substrate for a memory element, comprising a step in which a semiconductor substrate, which has a titanium-containing film that contains at least one of titanium and a titanium alloy and a metal tungsten film, is brought into contact with the etching composition for a semiconductor substrate for a memory element according to any one of items [1] to [8] to remove at least a part of the titanium-containing film.

### Advantageous Effect of the Invention

According to the present invention, an etching composition for a semiconductor substrate for a memory element capable of providing a semiconductor substrate for a memory element having improved performance is provided.

### BRIEF DESCRIPTION OF THE DRAWINGS

FIG. 1 is a schematic diagram of an etching step of a semiconductor substrate for a memory element.

FIG. 2 is a schematic diagram of a sample for evaluation (before etching) used in the Examples.

FIG. 3 is a schematic diagram of a sample for evaluation (after etching) used in the Examples.

### BEST MODE FOR CARRYING OUT THE INVENTION

Hereinafter, the mode for carrying out the present invention will be described in detail.

### <Etching Composition for Semiconductor Substrate for Memory Element>

The etching composition for a semiconductor substrate for a memory element of the present invention comprises an oxidizing agent (A), a fluorine compound (B), and a metal tungsten corrosion inhibiter (C). In this regard, the metal tungsten corrosion inhibiter (C) contains at least one selected from the group consisting of an ammonium salt represented by formula (1) and a heteroaryl salt having a substituted or unsubstituted alkyl group having 14 to 30 carbon atoms.

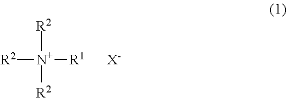

In formula (1) above, R¹ represents a substituted or unsubstituted alkyl group having 14 to 30 carbon atoms, a substituted or unsubstituted alkyl(poly)heteroalkylene group having 14 to 30 carbon atoms, or a substituted or unsubstituted aryl(poly)heteroalkylene group having 14 to 30 carbon atoms. Further, each R² independently represents a substituted or unsubstituted alkyl group having 1 to 30 carbon atoms, or a substituted or unsubstituted aryl group having 6 to 30 carbon atoms. X represents a halide ion, a hydroxide ion, an organic sulfonate ion, a tetrafluoroborate anion, or a hexafluorophosphate anion.

By using the above-described etching composition, a semiconductor substrate for a memory element having improved performance can be provided. Hereinafter, the present invention will be described with reference to the drawings. Note that the drawings may be illustrated in an exaggerated manner for the sake of explanation, and may be in dimensions different from actual dimensions.

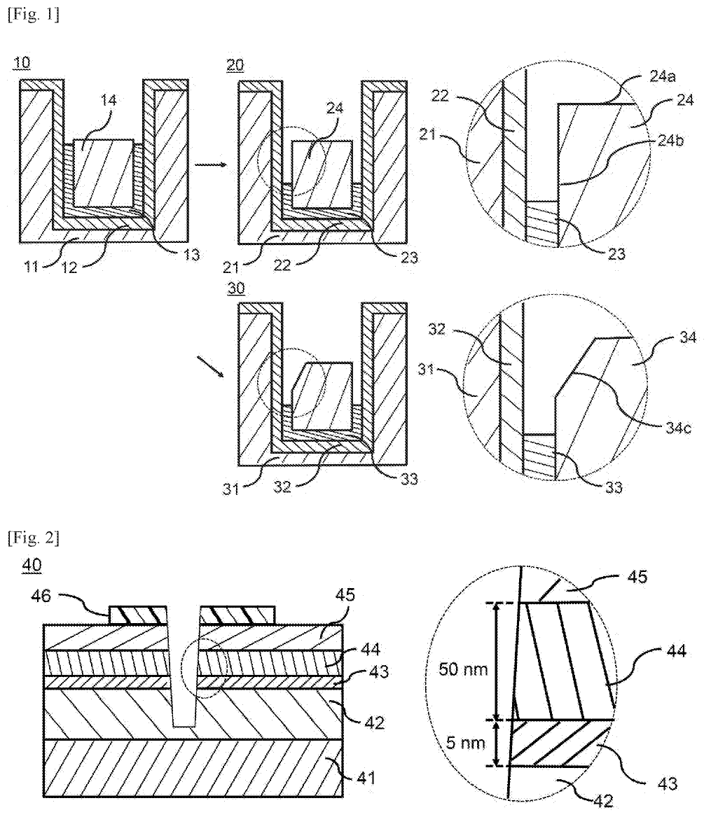

FIG. 1 is a schematic diagram of an etching step of a semiconductor substrate for a memory element. A semiconductor substrate for a memory element (before etching) 10 has a silicon substrate 11 having a recess, an insulating film 12 made of silicon dioxide, a barrier film (before etching) 13 made of titanium nitride, and a metal tungsten film 14. The semiconductor substrate for a memory element (before etching) 10 can be produced by sequentially forming an insulating film made of silicon dioxide, a barrier film made of titanium nitride, and a metal tungsten film on a silicon substrate having a recess, followed by planarization by CMP (chemical mechanical polishing), and selective etching of the barrier film and the metal tungsten film by dry etching or the like (CMP may be omitted). In the semiconductor substrate for a memory element (before etching) 10 in FIG. 1, both the barrier film and the metal tungsten film are selectively etched by dry etching, but it is also possible to employ a configuration in which only the metal tungsten film is selectively etched by dry etching.

By applying the etching composition for a semiconductor substrate for a memory element to the semiconductor substrate for a memory element (before etching) 10, a semiconductor substrate for a memory element (after etching) 20 can be obtained. Specifically, when the etching composition for a semiconductor substrate for a memory element is applied to the semiconductor substrate for a memory element (before etching) 10, the barrier film (before etching) 13 made of titanium nitride is selectively etched to provide a barrier film 23 made of titanium nitride. Meanwhile, the metal tungsten film 14 is not etched (corroded) or hardly etched (corroded), and a metal tungsten film 24 is provided.

However, when using a conventional etching composition for a semiconductor substrate for a memory element, there is a case where the above-described semiconductor substrate for a memory element (after etching) 20 is not obtained but a semiconductor substrate for a memory element (after etching) 30 is obtained. Specifically, when the etching composition for a semiconductor substrate for a memory element is applied to the semiconductor substrate for a memory element (before etching) 10, etching (corrosion) of the metal tungsten film 14 may proceed with etching of the barrier film (before etching) 13 made of titanium nitride. As a result, a metal tungsten film 34 of the semiconductor substrate for a memory element (after etching) 30 has a metal tungsten film corroded surface 34c. There is a case where a memory element produced by using the semiconductor substrate for a memory element (after etching) 30 in which the metal tungsten film is corroded does not provide desired physical properties.

It is not necessarily clear why etching (corrosion) of the metal tungsten film proceeds as described above, but for example, a possible reason therefor is as described below. A conventional etching composition for a semiconductor substrate for a memory element usually contains a metal tungsten corrosion inhibiter. It is considered that for this reason, the barrier film (before etching) 13 made of titanium nitride can be selectively etched without etching (corrosion) of the metal tungsten film 14. However, as selective etching of the barrier film 13 or 23 made of titanium nitride proceeds, a metal tungsten film side surface 24b is exposed. In this case, a narrow gap (for example, about 1 to 5 nm), which is composed of the metal tungsten film side surface 24b, the surface of the insulating film 22, and the top surface of the barrier film 23, is formed. Among the components of the etchant, it is expected that it is difficult for the metal tungsten corrosion inhibiter, which has a molecular size larger than those of an oxidizing agent and a fluorine compound that have relatively small molecular sizes and are involved in etching, to enter the above-described gap. That is, in this gap, since the concentration of the metal tungsten corrosion inhibiter is relatively reduced when compared to the concentrations of the oxidizing agent and the fluorine compound, etching (corrosion) of the metal tungsten film side surface 24b may proceed before the function of preventing etching is exerted by the metal tungsten corrosion inhibiter contained in the etching composition. Thus, it is inferred that the metal tungsten film 34 of the semiconductor substrate for a memory element (after etching) 30 has the metal tungsten film corroded surface 34c having a slope shape since etching (corrosion) from the direction of the metal tungsten film side surface 24b occurs. That is, a conventional etching composition for a semiconductor substrate for a memory element can suppress or prevent etching (corrosion) from the direction of a metal tungsten film surface 24a because of a metal tungsten corrosion inhibiter contained in the etching composition, but there is a case where the etching composition cannot sufficiently prevent etching (corrosion) from the direction of the metal tungsten film side surface 24b that is exposed with selective etching of the barrier film 13 made of titanium nitride.

In contrast, since the etching composition for a semiconductor substrate for a memory element of the present invention contains a predetermined metal tungsten corrosion inhibiter, the etching composition can prevent not only etching (corrosion) from the direction of the metal tungsten film surface 24a, but also etching (corrosion) from the direction of the metal tungsten film side surface 24b. Specifically, the predetermined metal tungsten corrosion inhibiter can quickly adsorb to the metal tungsten film side surface 24b, which is exposed as selective etching of the barrier film 13 made of titanium nitride proceeds, before etching (corrosion) of the metal tungsten film side surface 24b occurs. As a result, it is possible to produce a semiconductor substrate for a memory element in which there is no or almost no metal tungsten film corroded surface 34c.

In this specification, the “titanium alloy” means an alloy, which is obtained by adding, to titanium, at least one metal element other than titanium or at least one non-metal element, and which has metallic properties. In this regard, the content of titanium element in the titanium alloy is 20% by atomic weight or more, preferably 30% by atomic weight or more, more preferably 35% by atomic weight or more, and even more preferably 40 to 99.9% by atomic weight relative to the total atomic weight of the titanium alloy. Examples of elements other than titanium which may be contained in the titanium alloy include aluminum, oxygen, nitrogen, carbon, molybdenum, vanadium, niobium, iron, chromium, nickel, tin, hafnium, zirconium, palladium, ruthenium, and platinum. In the titanium alloy, these elements other than titanium may be contained solely, or two or more of them may be contained.

Hereinafter, the etching composition for a semiconductor substrate for a memory element of the present invention will be described in detail.

### [Oxidizing Agent (A)]

The oxidizing agent (A) has functions such as rendering the oxidation number of titanium atoms in titanium or a titanium alloy into the tetravalent state.

The oxidizing agent (A) is not particularly limited, and examples thereof include a peroxy acid, a halogen oxoacid, and a salt thereof.

Examples of the peroxy acid include hydrogen peroxide, persulfuric acid, percarbonic acid, perphosphoric acid, peracetic acid, perbenzoic acid, and meta-chloroperbenzoic acid.

Examples of the halogen oxoacid include: an oxoacid of chlorine such as hypochlorous acid, chlorous acid, chloric acid, and perchloric acid; an oxoacid of bromine such as hypobromous acid, bromous acid, bromic acid, and perbromic acid; and an oxoacid of iodine such as hypoiodous acid, iodous acid, iodic acid, and periodic acid.

Examples of the salt include: alkali metal salts such as lithium salts, sodium salts, potassium salts, rubidium salts, and cesium salts of the peroxy acid or halogen oxoacid; alkaline earth metal salts such as beryllium salts, magnesium salts, calcium salts, strontium salts, and barium salts of the peroxy acid or halogen oxoacid; metal salts such as aluminum salts, copper salts, zinc salts, and silver salts of the peroxy acid or halogen oxoacid; and ammonium salts of the peroxy acid or halogen oxoacid.

The oxidizing agent (A) described above is preferably hydrogen peroxide or an oxoacid of iodine, more preferably hydrogen peroxide, iodic acid, or periodic acid, even more preferably iodic acid or periodic acid, and for example, from the viewpoint that the Ti/W etching selectivity (etching amount of titanium and/or a titanium alloy/etching amount (corrosion amount) of metal tungsten) can be improved more, the oxidizing agent (A) is particularly preferably iodic acid.

As the oxidizing agent (A), the above-described substances may be used solely, or two or more of them may be used in combination. Specifically, in one embodiment, the oxidizing agent (A) preferably contains at least one selected from the group consisting of a peroxy acid, a halogen oxoacid, and a salt thereof, more preferably contains at least one selected from the group consisting of hydrogen peroxide and an oxoacid of iodine, even more preferably contains at least one selected from the group consisting of hydrogen peroxide, iodic acid, and periodic acid, particularly preferably contains at least one selected from the group consisting of iodic acid and periodic acid, and most preferably contains periodic acid.

The addition ratio of the oxidizing agent (A) is preferably from 0.0001 to 10% by mass, more preferably from 0.001 to 5% by mass, even more preferably from 0.003 to 3% by mass, and particularly preferably from 0.01 to 2% by mass relative to the total mass of the etching composition for a semiconductor substrate for a memory element.

### [Fluorine Compound (B)]

The fluorine compound (B) has functions such as facilitating etching of titanium or titanium alloy changed to the tetravalent state.

The fluorine compound (B) is not particularly limited, and examples thereof include hydrogen fluoride (HF), tetrafluoroboric acid (HBF₄), hexafluorosilicic acid (H₂SiF₆), hexafluorozirconic acid (H₂ZrF₆), hexafluorotitanic acid (H₂TiF₆), hexafluorophosphoric acid (HPF₆), hexafluoroaluminic acid (H₂AlF₆), hexafluorogermanic acid (H₂GeF₆), and a salt thereof.

In this regard, examples of the salt include an ammonium salt such as ammonium fluoride (NH₄F), ammonium acid fluoride (NH₄F·HF), ammonium tetrafluoroborate (NH₄BF₄), ammonium hexafluorosilicate ((NH₄)₂SiF₆), and tetramethylammonium tetrafluoroborate (N(CH₃)₄BF₄).

Among the above-described examples, the fluorine compound (B) is preferably hydrogen fluoride (HF), tetrafluoroboric acid (HBF₄), hexafluorosilicic acid (H₂SiF₆), or a salt thereof, more preferably hydrogen fluoride (HF), ammonium fluoride (NH₄F), ammonium acid fluoride (NH₄F·HF), or hexafluorosilicic acid (H₂SiF₆), and for example, from the viewpoint that corrosion of metal tungsten can be prevented more, and that the Ti/W etching selectivity can be improved more, the fluorine compound (B) is even more preferably ammonium acid fluoride (NH₄F·HF) or hexafluorosilicic acid (H₂SiF₆), and particularly preferably hexafluorosilicic acid (H₂SiF₆).

As the fluorine compound (B), the above-described substances may be used solely, or two or more of them may be used in combination. Specifically, in a preferred embodiment, the fluorine compound (B) preferably contains at least one selected from the group consisting of hydrogen fluoride (HF), tetrafluoroboric acid (HBF₄), hexafluorosilicic acid (H₂SiF₆), hexafluorozirconic acid (H₂ZrF₆), hexafluorotitanic acid (H₂TiF₆), hexafluorophosphoric acid (HPF₆), hexafluoroaluminic acid (H₂AlF₆), hexafluorogermanic acid (H₂GeF₆), and a salt thereof, more preferably contains at least one selected from the group consisting of hydrogen fluoride (HF), tetrafluoroboric acid (HBF₄), hexafluorosilicic acid (H₂SiF₆), and a salt thereof, even more preferably contains at least one selected from the group consisting of hydrogen fluoride (HF), ammonium fluoride (NH₄F), ammonium acid fluoride (NH₄F·HF), and hexafluorosilicic acid (H₂SiF₆), particularly preferably contains at least one selected from the group consisting of ammonium acid fluoride (NH₄F·HF) and hexafluorosilicic acid (H₂SiF₆), and most preferably contains hexafluorosilicic acid (H₂SiF₆).

The addition ratio of the fluorine compound (B) is preferably from 0.005 to 10% by mass, more preferably from 0.01 to 3% by mass, even more preferably from 0.01 to 1% by mass, and particularly preferably from 0.03 to 0.5% by mass relative to the total mass of the etching composition for a semiconductor substrate for a memory element.

### [Metal Tungsten Corrosion Inhibiter (C)]

The metal tungsten corrosion inhibiter (C) has the function to quickly adsorb not only to ordinary metal tungsten, but also to the side surface of metal tungsten which is exposed with etching of an adjacent titanium-containing film containing titanium and/or a titanium alloy. This reduces the reactivity of the side surface of metal tungsten, and can suitably prevent or suppress etching (corrosion) from the side surface of metal tungsten.

The metal tungsten corrosion inhibiter (C) is not particularly limited, but contains at least one selected from the group consisting of an ammonium salt represented by formula (1) and a heteroaryl salt having a substituted or unsubstituted alkyl group having 14 to 30 carbon atoms.

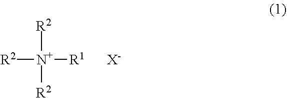

In formula (1) above, R¹ represents a substituted or unsubstituted alkyl group having 14 to 30 carbon atoms, a substituted or unsubstituted alkyl(poly)heteroalkylene group having 14 to 30 carbon atoms, or a substituted or unsubstituted aryl(poly)heteroalkylene group having 14 to 30 carbon atoms.

The alkyl group having 14 to 30 carbon atoms is not particularly limited, and examples thereof include a tetradecyl group, a pentadecyl group, a hexadecyl group, a heptadecyl group, an octadecyl group, a nonadecyl group, an icosyl group, a docosyl group, a tetracosyl group, a hexacosyl group, an octacosyl group, and a triacontyl group.

In the case where the substituted or unsubstituted alkyl group having 14 to 30 carbon atoms has a substituent (a substituted alkyl group having 14 to 30 carbon atoms), the substituent is not particularly limited, and examples thereof include: a halogen atom such as a fluorine atom, a chlorine atom, a bromine atom, and an iodine atom; an aryl group having 6 to 20 carbon atoms such as a phenyl group and a naphthyl group; an alkoxy group having 1 to 6 carbon atoms such as a methoxy group, an ethoxy group, and a propyloxy group; a hydroxy group; a cyano group; and a nitro group. Note that the substituted alkyl group may have one substituent, or may have two or more substituents. Further, the substituted alkyl group having 14 to 30 carbon atoms means that the total number of the carbon number of the substituent and the carbon number of the alkyl group is 14 to 30. That is, in the case of the substituted alkyl group having 14 to 30 carbon atoms, according to the carbon number of the substituent, the carbon number of the alkyl group can be adjusted to 14 or less (e.g., an alkyl group having 8 to 13 carbon atoms such as an octyl group, a decyl group, and a dodecyl group).

The alkyl(poly)heteroalkylene group having 14 to 30 carbon atoms is represented by —(CₙH₂ₙ—Z—)ₘ—R³. In this regard, each n is independently from 1 to 5, preferably from 1 to 3, and more preferably from 1 to 2. m is from 1 to 5, and preferably from 1 to 2. Each Z is independently an oxygen atom (O), a sulfur atom (S), or a phosphorus atom (P), and preferably an oxygen atom (O). R³ represents an alkyl group having 1 to 30 carbon atoms, and examples thereof include a methyl group, an ethyl group, a propyl group, an isopropyl group, a butyl group, a pentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, and an icosyl group.

In the case where the substituted or unsubstituted alkyl(poly)heteroalkylene group having 14 to 30 carbon atoms has a substituent (a substituted alkyl(poly)heteroalkylene group having 14 to 30 carbon atoms), the substituent is not particularly limited, and examples thereof include: a halogen atom such as a fluorine atom, a chlorine atom, a bromine atom, and an iodine atom; an aryl group having 6 to 20 carbon atoms such as a phenyl group and a naphthyl group; an alkoxy group having 1 to 6 carbon atoms such as a methoxy group, an ethoxy group, and a propyloxy group; a hydroxy group; a cyano group; and a nitro group. Note that the substituent is usually substituted with a hydrogen atom in R³. Further, the substituted alkyl(poly)heteroalkylene group may have one substituent, or may have two or more substituents. Moreover, the substituted alkyl(poly)heteroalkylene group having 14 to 30 carbon atoms means that the total number of the carbon number of the substituent and the carbon number of the alkyl(poly)heteroalkylene group is 14 to 30. That is, in the case of the substituted alkyl(poly)heteroalkylene group having 14 to 30 carbon atoms, according to the carbon number of the substituent, the carbon number of the alkyl(poly)heteroalkylene group can be adjusted to 14 or less (e.g., an alkyl group having 8 to 13 carbon atoms such as an octyl group, a decyl group, and a dodecyl group).

The aryl(poly)heteroalkylene group having 14 to 30 carbon atoms is represented by —(CₙH₂ₙ—Z—)ₘ—Ar. In this regard, each n is independently from 1 to 5, preferably from 1 to 3, and more preferably from 1 to 2. m is from 1 to 5, and preferably from 1 to 2. Each Z is independently an oxygen atom (O), a sulfur atom (S), or a phosphorus atom (P), and preferably an oxygen atom (O). Ar represents an aryl group having 6 to 18 carbon atoms, and examples thereof include a phenyl group, a naphthyl group, and an anthracenyl group.

In the case where the substituted or unsubstituted aryl(poly)heteroalkylene group having 14 to 30 carbon atoms has a substituent (a substituted aryl(poly)heteroalkylene group having 14 to 30 carbon atoms), the substituent is not particularly limited, and examples thereof include: a halogen atom such as a fluorine atom, a chlorine atom, a bromine atom, and an iodine atom; an alkyl group having 1 to 10 carbon atoms such as a methyl group, an ethyl group, a propyl group, an isopropyl group, a butyl group, a 1,1-dimethylbutyl group, a 2,2-dimethylbutyl group, and a 1,1,3,3-tetramethylbutyl group; an alkoxy group having 1 to 6 carbon atoms such as a methoxy group, an ethoxy group, and a propyloxy group; a hydroxy group; a cyano group; and a nitro group. Note that the substituent is usually substituted with a hydrogen atom in Ar. Further, the substituted aryl(poly)heteroalkylene group may have one substituent, or may have two or more substituents. Moreover, the substituted aryl(poly)heteroalkylene group having 14 to 30 carbon atoms means that the total number of the carbon number of the substituent and the carbon number of the aryl(poly)heteroalkylene group is 14 to 30. That is, in the case of the substituted aryl(poly)heteroalkylene group having 14 to 30 carbon atoms, according to the carbon number of the substituent, the carbon number of the aryl(poly)heteroalkylene group can be adjusted to 14 or less (e.g., an alkyl group having 8 to 13 carbon atoms such as an octyl group, a decyl group, and a dodecyl group).

In one embodiment, R¹ is preferably a substituted or unsubstituted alkyl(poly)heteroalkylene group having 14 to 30 carbon atoms or a substituted or unsubstituted aryl(poly)heteroalkylene group having 14 to 30 carbon atoms, more preferably a substituted or unsubstituted aryl(poly)heteroalkylene group having 14 to 20 carbon atoms, even more preferably a substituted or unsubstituted aryl(poly)heteroalkylene group having 16 to 20 carbon atoms, particularly preferably a substituted or unsubstituted aryl(poly)heteroalkylene group having 18 to 20 carbon atoms, and most preferably a p-(1,1,3,3-tetramethylbutyl)phenyldi(oxyethylene) (p-CH₃C(CH₃)₂CH₂C(CH₃)₂-Ph-(O—C₂H₄)₂—) group.

In another embodiment, R¹ is preferably a substituted or unsubstituted alkyl group having 14 to 25 carbon atoms or a substituted or unsubstituted aryl(poly)heteroalkylene group having 14 to 25 carbon atoms, more preferably a substituted or unsubstituted alkyl group having 14 to 20 carbon atoms or a substituted or unsubstituted aryl(poly)heteroalkylene group having 14 to 20 carbon atoms, even more preferably a tetradecyl group, a hexadecyl group, an octadecyl group, or a p-(1,1,3,3-tetramethylbutyl)phenyldi(oxyethylene) (p-CH₃C(CH₃)₂CH₂C(CH₃)₂-Ph-(O—C₂H₄)₂—) group, particularly preferably a hexadecyl group, an octadecyl group, or a p-(1,1,3,3-tetramethylbutyl) phenyldi(oxyethylene) (p-CH:C(CH₃)₂CH₂C(CH₃)₂-Ph-(O—C₂H₄)₂—) group, and most preferably a p-(1,1,3,3-tetramethylbutyl)phenyldi(oxyethylene) (p-CH₃C(CH₃)₂CH₂C(CH₃)₂-Ph-(O—C₂H₄)₂—) group.

Further, each R² is independently a substituted or unsubstituted alkyl group having 1 to 30 carbon atoms or a substituted or unsubstituted aryl group having 6 to 30 carbon atoms.

The alkyl group having 1 to 30 carbon atoms is not particularly limited, and examples thereof include a methyl group, an ethyl group, a propyl group, an isopropyl group, a butyl group, an isobutyl group, a sec-butyl group, a tert-butyl group, a pentyl group, a hexyl group, a heptyl group, an octyl group, a nonyl group, a decyl group, a dodecyl group, a tetradecyl group, a hexadecyl group, an octadecyl group, a nonadecyl group, and an icosyl group.

In the case where the substituted or unsubstituted alkyl group having 1 to 30 carbon atoms has a substituent (a substituted alkyl group having 1 to 30 carbon atoms), examples of the substituent include: a halogen atom such as a fluorine atom, a chlorine atom, a bromine atom, and an iodine atom; an aryl group having 6 to 20 carbon atoms such as a phenyl group and a naphthyl group; an alkoxy group having 1 to 6 carbon atoms such as a methoxy group, an ethoxy group, and a propyloxy group; a hydroxy group; a cyano group; and a nitro group. Note that the substituted alkyl group may have one substituent, or may have two or more substituents. Further, the substituted alkyl group having 1 to 30 carbon atoms means that the total number of the carbon number of the substituent and the carbon number of the alkyl group is 1 to 30.

The aryl group having 6 to 30 carbon atoms is not particularly limited, and examples thereof include a phenyl group, a naphthyl group, and a biphenyl group.

In the case where the substituted or unsubstituted aryl group having 6 to 30 carbon atoms has a substituent (a substituted aryl group having 6 to 30 carbon atoms), examples of the substituent include: a halogen atom such as a fluorine atom, a chlorine atom, a bromine atom, and an iodine atom; an alkyl group having 1 to 10 carbon atoms such as a methyl group, an ethyl group, a propyl group, and an isopropyl group; an alkoxy group having 1 to 6 carbon atoms such as a methoxy group, an ethoxy group, and a propyloxy group; a hydroxy group; a cyano group; and a nitro group. Note that the substituted aryl group may have one substituent, or may have two or more substituents. Further, the substituted aryl group having 6 to 30 carbon atoms means that the total number of the carbon number of the substituent and the carbon number of the alkyl group is 6 to 30.

Among them, R² is preferably a substituted or unsubstituted alkyl group having 1 to 30 carbon atoms, more preferably a methyl group, an ethyl group, a propyl group, an isopropyl group, a hexyl group, an octyl group, a decyl group, a dodecyl group, a tetradecyl group, a hexadecyl group, an octadecyl group, a benzyl group, a hydroxymethyl group, or a 2-hydroxyethyl group, even more preferably a methyl group, an ethyl group, a benzyl group, or a 2-hydroxyethyl group, particularly preferably a methyl group or a benzyl group, and most preferably a methyl group. In another embodiment, R² is preferably an alkyl group having 1 to 10 carbon atoms substituted with an aryl group having 6 to 20 carbon atoms, more preferably an alkyl group having 1 to 5 carbon atoms substituted with a phenyl group, even more preferably a benzyl group or a phenylethyl group, and particularly preferably a benzyl group.

X is a halide ion (a fluoride ion, a chloride ion, a bromide ion, an iodide ion, etc.), a hydroxide ion, an organic sulfonate ion (a methanesulfonate ion, a p-toluenesulfonate ion, etc.), a tetrafluoroborate anion, or a hexafluorophosphate anion. Among them, X is preferably a halide ion, and more preferably a chloride ion or a bromide ion.

Specific examples of the ammonium salt represented by formula (1) in which R¹ is a substituted or unsubstituted alkyl group having 14 to 30 carbon atoms include: an ammonium salt having a tetradecyl group such as tetradecyltrimethylammonium bromide and benzyldimethyltetradecylammonium chloride; an ammonium salt having a hexadecyl group such as hexadecyltrimethylammonium chloride, hexadecyltrimethylammonium bromide, hexadecyltrimethylammonium p-toluenesulfonate, hexadecyltrimethylammonium hydroxide, ethylhexadecyldimethylammonium chloride, ethylhexadecyldimethylammonium bromide, and benzyldimethylhexadecylammonium chloride; and an ammonium salt having an octadecyl group such as trimethyloctadecylammonium chloride, trimethyloctadecylammonium bromide, dimethyldioctadecylammonium chloride, dimethyldioctadecylammonium bromide, and benzyldimethyloctadecylammonium chloride.

Specific examples of the ammonium salt represented by formula (1) in which R¹ is a substituted or unsubstituted alkyl(poly)heteroalkylene group having 14 to 30 carbon atoms include trimethylpropyldi(oxyethylene)ammonium chloride and trimethylpropyl(oxyethylenethioethylene)ammonium chloride.

Specific examples of the ammonium salt represented by formula (1) in which R¹ is a substituted or unsubstituted aryl(poly)heteroalkylene group having 14 to 30 carbon atoms include benzyldimethyl-2-{2-[4-(1,1,3,3-tetramethylbutyl)phenoxy]ethoxy}ethylammonium chloride (benzethonium chloride) and benzyldimethylphenyldi(oxyethylene)ammonium chloride.

Further, the heteroaryl salt having a substituted or unsubstituted alkyl group having 14 to 30 carbon atoms is not particularly limited, and examples thereof include a salt of a heteroaryl cation in which at least one of nitrogen atoms in a substituted or unsubstituted nitrogen atom-containing heteroaryl ring is bonded to a substituted or unsubstituted alkyl group having 14 to 30 carbon atoms.

The nitrogen atom-containing heteroaryl ring is not particularly limited, and examples thereof include a ring such as imidazole, pyrazole, oxazole, isoxazole, thiazole, isothiazole, pyridine, pyrazine, pyridazine, pyrimidine, quinoline, and isoquinoline.

In the case where the nitrogen atom-containing heteroaryl ring has a substituent, examples of the substituent include: a halogen atom such as a fluorine atom, a chlorine atom, a bromine atom, and an iodine atom; an alkyl group having 1 to 4 carbon atoms such as a methyl group, an ethyl group, a propyl group, and an isopropyl group; an aryl group having 6 to 20 carbon atoms such as a phenyl group and a naphthyl group; an alkoxy group having 1 to 6 carbon atoms such as a methoxy group, an ethoxy group, and a propyloxy group; a hydroxy group; a cyano group; and a nitro group.

The alkyl group having 14 to 30 carbon atoms is not particularly limited, and examples thereof include a tetradecyl group, a pentadecyl group, a hexadecyl group, a heptadecyl group, an octadecyl group, a nonadecyl group, an icosyl group, a docosyl group, a tetracosyl group, a hexacosyl group, an octacosyl group, and a triacontyl group.

In the case where the substituted or unsubstituted alkyl group having 14 to 30 carbon atoms has a substituent (a substituted alkyl group having 14 to 30 carbon atoms), examples of the substituent include: a halogen atom such as a fluorine atom, a chlorine atom, a bromine atom, and an iodine atom; an alkyl group having 1 to 4 carbon atoms such as a methyl group, an ethyl group, a propyl group, and an isopropyl group; an aryl group having 6 to 20 carbon atoms such as a phenyl group and a naphthyl group; an alkoxy group having 1 to 6 carbon atoms such as a methoxy group, an ethoxy group, and a propyloxy group; a hydroxy group; a cyano group; and a nitro group. Note that the substituted alkyl group may have one substituent, or may have two or more substituents. Further, the substituted alkyl group having 14 to 30 carbon atoms means that the total number of the carbon number of the substituent and the carbon number of the alkyl group is 14 to 30. That is, in the case of the substituted alkyl group having 14 to 30 carbon atoms, according to the carbon number of the substituent, the carbon number of the alkyl group can be adjusted to 14 or less (e.g., an alkyl group having 8 to 13 carbon atoms such as an octyl group, a decyl group, and a dodecyl group).

Among them, the substituted or unsubstituted alkyl group having 14 to 30 carbon atoms is preferably a substituted or unsubstituted alkyl group having 14 to 20 carbon atoms, more preferably an alkyl group having 14 to 20 carbon atoms, even more preferably a tetradecyl group, a hexadecyl group, or an octadecyl group, and particularly preferably a hexadecyl group or an octadecyl group.

The counter anion of the heteroaryl cation having a substituted or unsubstituted alkyl group having 14 to 30 carbon atoms is not particularly limited, and examples thereof include: a halide ion such as a fluoride ion, a chloride ion, a bromide ion, and an iodide ion; a hydroxide ion; an organic sulfonate ion such as a methanesulfonate ion and a p-toluenesulfonate ion; a tetrafluoroborate anion; and a hexafluorophosphate anion. Among them, the counter anion is preferably a halide ion, and more preferably a chloride ion or a bromide ion.

Specific examples of the heteroaryl salt having a substituted or unsubstituted alkyl group having 14 to 30 carbon atoms include: an imidazolium salt such as 1-tetradecyl-3-methylimidazolium chloride, 1-tetradecyl-3-methylimidazolium bromide, 1-hexadecyl-3-methylimidazolium chloride, 1-hexadecyl-3-methylimidazolium bromide, 1-octadecyl-3-methylimidazolium chloride, and 1-octadecyl-3-methylimidazolium bromide; an oxazolium salt such as 3-tetradecyloxazolium chloride, 3-hexadecyloxazolium chloride, and 3-octadecyloxazolium chloride; a thiazolium salt such as 3-tetradecylthiazolium chloride, 3-hexadecylthiazolium chloride, and 3-octadecylthiazolium chloride; a pyridinium salt such as 1-tetradecylpyridinium chloride, 1-tetradecylpyridinium bromide, 1-hexadecylpyridinium chloride, 1-hexadecylpyridinium bromide, 1-octadecylpyridinium chloride, and 1-octadecylpyridinium bromide; a pyrimidinium salt such as 1-tetradecylpyrimidinium chloride, 1-hexadecylpyrimidinium chloride, and 1-octadecylpyrimidinium chloride; a quinolinium salt such as tetradecylquinolinium chloride, hexadecylquinolinium chloride, and octadecylquinolinium chloride; and an isoquinolinium salt such as tetradecylisoquinolinium chloride, hexadecylisoquinolinium chloride, and octadecylisoquinolinium chloride. Furthermore, these substances may be used in the form of a hydrate thereof.

Among them, for example, from the viewpoint that the Ti/W etching selectivity can be improved more, the metal tungsten corrosion inhibiter (C) is preferably an ammonium salt represented by formula (1), more preferably an ammonium salt represented by formula (1) (wherein R¹ is a substituted or unsubstituted alkyl group having 15 to 20 carbon atoms, a substituted or unsubstituted alkyl(poly)heteroalkylene group having 15 to 20 carbon atoms, or a substituted or unsubstituted aryl(poly)heteroalkylene group having 15 to 20 carbon atoms), even more preferably an ammonium salt represented by formula (1) (wherein R¹ is an alkyl group having 17 to 20 carbon atoms or a substituted aryl(poly)heteroalkylene group having 17 to 20 carbon atoms), particularly preferably an ammonium salt represented by formula (1) (wherein R¹ is a substituted aryl(poly)heteroalkylene group having 17 to 20 carbon atoms), and most preferably benzethonium chloride or benzethonium bromide.

As the metal tungsten corrosion inhibiter (C), the above-described substances may be used solely, or two or more of them may be used in combination. Specifically, in a preferred embodiment, the metal tungsten corrosion inhibiter (C) preferably contains at least one ammonium salt represented by formula (1), more preferably contains at least one ammonium salt represented by formula (1) (wherein R¹ is a substituted or unsubstituted alkyl group having 15 to 20 carbon atoms, a substituted or unsubstituted alkyl(poly)heteroalkylene group having 15 to 20 carbon atoms, or a substituted or unsubstituted aryl(poly)heteroalkylene group having 15 to 20 carbon atoms), even more preferably contains at least one ammonium salt represented by formula (1) (wherein R¹ is an alkyl group having 17 to 20 carbon atoms or a substituted aryl(poly)heteroalkylene group having 17 to 20 carbon atoms), particularly preferably contains at least one ammonium salt represented by formula (1) (wherein R¹ is a substituted aryl(poly)heteroalkylene group having 17 to 20 carbon atoms), and most preferably contains at least one of benzethonium chloride and benzethonium bromide.

The addition ratio of the metal tungsten corrosion inhibiter (C) is preferably from 0.0001 to 5% by mass, more preferably from 0.001 to 1% by mass, even more preferably from 0.003 to 0.5% by mass, and particularly preferably from 0.004 to 0.08% by mass relative to the total mass of the etching composition for a semiconductor substrate for a memory element.

### [pH Adjuster (D)]

The etching composition for a semiconductor substrate for a memory element may contain a pH adjuster (D) according to need. In one embodiment, the etching composition for a semiconductor substrate for a memory element preferably further contains a pH adjuster (D).

As the pH adjuster (D), for example, an acid or alkali other than the oxidizing agent (A) and the fluorine compound (B) can be used.

Examples of the acid include hydrogen chloride, hydrogen bromide, hydrogen iodide, sulfuric acid, nitric acid, methanesulfonic acid, trifluoromethanesulfonic acid, benzenesulfonic acid, p-toluenesulfonic acid, 10-camphorsulfonic acid, and a salt thereof. In this regard, examples of the salt include: an ammonium salt such as ammonium chloride, ammonium bromide, ammonium iodide, ammonium sulfate, and ammonium nitrate; and an alkylammonium salt such as methylamine hydrochloride, dimethylamine hydrochloride, dimethylamine hydrobromide, and methylamine sulfate.

Examples of the alkali include lithium hydroxide, sodium hydroxide, potassium hydroxide, rubidium hydroxide, cesium hydroxide, beryllium hydroxide, magnesium hydroxide, calcium hydroxide, strontium hydroxide, barium hydroxide, ammonia, and triethylamine.

Among the above-described examples, the pH adjuster (D) is preferably hydrogen chloride, hydrogen bromide, hydrogen iodide, sulfuric acid, nitric acid, methanesulfonic acid, or ammonia, more preferably hydrogen chloride, sulfuric acid, or methanesulfonic acid, and for example, from the viewpoint that corrosion of metal tungsten can be prevented more, and that the Ti/W etching selectivity can be improved more, the pH adjuster (D) is even more preferably hydrogen chloride or methanesulfonic acid, and particularly preferably methanesulfonic acid.

As the pH adjuster (D), the above-described substances may be used solely, or two or more of them may be used in combination. Specifically, in a preferred embodiment, the pH adjuster (D) preferably contains at least one selected from the group consisting of hydrogen chloride, hydrogen bromide, hydrogen iodide, sulfuric acid, nitric acid, methanesulfonic acid, and ammonia, more preferably contains at least one selected from the group consisting of hydrogen chloride, sulfuric acid, and methanesulfonic acid, even more preferably contains at least one selected from the group consisting of hydrogen chloride and methanesulfonic acid, and particularly preferably contains methanesulfonic acid.

The addition ratio of the pH adjuster (D) varies depending on the pH of the etching composition for a semiconductor substrate for a memory element before adjustment, but it is preferably from 0.0001 to 5% by mass, more preferably from 0.01 to 3% by mass, even more preferably from 0.1 to 1% by mass, and particularly preferably from 0.3 to 0.75% by mass relative to the total mass of the etching composition for a semiconductor substrate for a memory element.

### [Water]

The etching composition for a semiconductor substrate for a memory element preferably contains water. Said water has functions such as homogeneously dispersing and diluting each component contained in the etching composition for a semiconductor substrate for a memory element.

The water is not particularly limited, but it is preferably water from which metal ions, organic impurities, particles, etc. have been removed by distillation, ion exchange treatment, filtering treatment, adsorption treatment or the like. Pure water is more preferred, and ultrapure water is particularly preferred.

The addition ratio of the water is preferably 50% by mass or more, more preferably 80% by mass or more, even more preferably 90% by mass or more, and particularly preferably from 90 to 99.5% by mass relative to the total mass of the etching composition for a semiconductor substrate for a memory element.

### [Organic Solvent (E)]

The etching composition for a semiconductor substrate for a memory element may contain an organic solvent (E) according to need. In one embodiment, the etching composition for a semiconductor substrate for a memory element preferably further contains an organic solvent (E). It is considered that the organic solvent (E) has the function to suitably prevent or suppress etching (corrosion) from the side surface of metal tungsten since the organic solvent (E) further reduces the surface tension of the etching composition for a semiconductor substrate for a memory element, and therefore the metal tungsten corrosion inhibiter tends to easily enter a micro space of the metal tungsten film side surface which is generated as selective etching of the titanium-containing film (barrier film) containing titanium/a titanium alloy proceeds.

The organic solvent (E) is not particularly limited, and examples thereof include: an alcohol such as a monoalcohol (methanol, ethanol, 1-propanol, 2-propanol, 1-butanol, tert-butanol, 1-pentanol, 1-hexanol, 1-heptanol, 1-octanol, 1-nonanol, 1-decanol, etc.), a diol (ethylene glycol, propylene glycol, neopentyl glycol, 1,2-hexanediol, 1,6-hexanediol, 2-ethylhexane-1,3-diol, etc.), and a polyhydric alcohol (glycerin, etc.); an ether such as dimethyl ether, diethyl ether, tetrahydrofuran, and 1,4-dioxane; a glycol ether such as diethylene glycol monomethyl ether, diethylene glycol monoethyl ether, diethylene glycol monobutyl ether, propylene glycol monomethyl ether, propylene glycol monoethyl ether, dipropylene glycol monomethyl ether, tripropylene glycol monomethyl ether, dipropylene glycol dimethyl ether, dipropylene glycol monoethyl ether, propylene glycol n-propyl ether, dipropylene glycol n-propyl ether, tripropylene glycol n-propyl ether, propylene glycol n-butyl ether, dipropylene glycol n-butyl ether, tripropylene glycol n-butyl ether, and propylene glycol phenyl ether; and an amide such as dimethylformamide, diethylformamide, dimethylacetamide, and N-methylpyrrolidone.

Among them, from the viewpoint of a high boiling point, stability, etc., the organic solvent (E) is preferably an alcohol, more preferably a monoalcohol or a diol, even more preferably 1-hexanol, 1-heptanol, 1-octanol, 1-nonanol, 1-decanol, 1,2-hexanediol, 1,6-hexanediol, or 2-ethylhexane-1,3-diol, still more preferably 1-hexanol, 1-heptanol, 1-octanol, or 2-ethylhexane-1,3-diol, and particularly preferably 1-hexanol, 1-heptanol, or 1-octanol.

As the organic solvent (E), the above-described substances may be used solely, or two or more of them may be used in combination. Specifically, in a preferred embodiment, the organic solvent (E) preferably contains at least one alcohol, more preferably contains at least one selected from the group consisting of a monoalcohol and a diol, even more preferably contains at least one selected from the group consisting of 1-hexanol, 1-heptanol, 1-octanol, 1-nonanol, 1-decanol, 1,2-hexanediol, 1,6-hexanediol, and 2-ethylhexane-1,3-diol, particularly preferably contains at least one selected from the group consisting of 1-hexanol, 1-heptanol, 1-octanol, and 2-ethylhexane-1,3-diol, and most preferably contains at least one selected from the group consisting of 1-hexanol, 1-heptanol, and 1-octanol.

The addition ratio of the organic solvent (E) varies depending on the composition, surface tension, etc. of the etching composition for a semiconductor substrate for a memory element before adjustment, but it is preferably 50% by mass or less, more preferably 10% by mass or less, even more preferably from 0.01 to 7.5% by mass, particularly preferably from 0.05 to 5% by mass, and most preferably from 0.5 to 3% by mass relative to the total mass of the etching composition for a semiconductor substrate for a memory element.

### [Iodine Scavenger]

When the oxidizing agent (A) contains an oxoacid of iodine, the etching composition for a semiconductor substrate for a memory element preferably further contains an iodine scavenger.

The iodine scavenger is not particularly limited, and examples thereof include: an aliphatic ketone such as acetone, butanone, 2-methyl-2-butanone, 3,3-dimethyl-2-butanone, 4-hydroxy-2-butanone, 2-pentanone, 3-pentanone, 3-methyl-2-pentanone, 4-methyl-2-pentanone, 2-methyl-3-pentanone, 5-methyl-3-pentanone, 2,4-dimethyl-3-pentanone, 5-hydroxy-2-pentanone, 4-hydroxy-4-methyl-2-pentanone, 2-hexanone, 3-hexanone, 2-heptanone, 3-heptanone, 4-heptanone, 5-methyl-2-heptanone, 5-methyl-3-heptanone, 2,6-dimethyl-4-heptanone, 2-octanone, 3-octanone, 4-octanone, cyclohexanone, 2,6-dimethylcyclohexanone, 2-acetylcyclohexanone, menthone, cyclopentanone, and dicyclohexyl ketone; an aliphatic diketone such as 2,5-hexanedione, 2,4-pentanedione, and acetylacetone; and an aromatic ketone such as acetophenone, 1-phenylethanone, and benzophenone. Among them, the iodine scavenger is preferably an aliphatic ketone, more preferably 4-methyl-2-pentanone, 5-methyl-3-pentanone, 2,4-dimethyl-3-pentanone, or cyclohexanone, and even more preferably 4-methyl-2-pentanone. As the iodine scavenger, the above-described substances may be used solely, or two or more of them may be used in combination.

### [Low Dielectric Constant Passivation Agent]

The etching composition for a semiconductor substrate for a memory element may further contain a low dielectric constant passivation agent. The low dielectric constant passivation agent has a function to prevent or suppress etching of a low dielectric constant film (e.g., an insulating film).

The low dielectric constant passivation agent is not particularly limited, and examples thereof include: boric acid; a borate such as ammonium pentaborate and sodium tetraborate; and a carboxylic acid such as 3-hydroxy-2-naphthoic acid, malonic acid, and iminodiacetic acid.

As the low dielectric constant passivation agent, the above-described substances may be used solely, or two or more of them may be used in combination.

The addition ratio of the low dielectric constant passivation agent is preferably from 0.01 to 2% by mass, more preferably from 0.02 to 1% by mass, and even more preferably from 0.03 to 0.5% by mass relative to the total mass of the etching composition for a semiconductor substrate for a memory element.

### [Additive]

The etching composition for a semiconductor substrate for a memory element may further contain an additive. Examples of the additive include a surfactant, a chelating agent, an antifoaming agent, and a silicon-containing compound.

### [Physical Properties]

The surface tension of the etching composition for a semiconductor substrate for a memory element is preferably 50 mN/m or less, more preferably 40 mN/m or less, even more preferably from 10 to 35 mN/m, particularly preferably from 20 to 32 mN/m, and most preferably from 25 to 30 mN/m. When the surface tension of the etching composition for a semiconductor substrate for a memory element is 50 mN/m or less, it is preferred because etching (corrosion) from the side surface of metal tungsten can be suitably prevented or suppressed since the metal tungsten corrosion inhibiter tends to easily enter a micro space of the metal tungsten film side surface which is generated as selective etching of the titanium-containing film (barrier film) containing titanium/a titanium alloy proceeds. In this specification, the surface tension is measured by the method described in the Examples. Further, the surface tension of the etching composition for a semiconductor substrate for a memory element can be adjusted, for example, by the use of a metal tungsten corrosion inhibiter (C) having a larger carbon number, the addition of an organic solvent (E) having higher hydrophobicity, or the like.

The etching composition for a semiconductor substrate for a memory element has a pH ranging preferably from 0.1 to 5.0, more preferably from 0.5 to 3.0, even more preferably from 0.8 to 1.5, and particularly preferably from 0.8 to 1.3. When the pH of the etching composition for a semiconductor substrate for a memory element is within the above-described range, it is preferred because the amount of etching (corrosion) of metal tungsten can be reduced. In this specification, the pH is measured by the method described in the Examples. Further, the pH of the etching composition for a semiconductor substrate for a memory element can be adjusted, for example, by the addition of the pH adjuster (D).

### <Method for Producing Semiconductor Substrate for Memory Element>

According to one aspect of the present invention, a method for producing a semiconductor substrate for a memory element is provided. The production method comprises a step in which a semiconductor substrate, which has a titanium-containing film that contains at least one of titanium and a titanium alloy and a metal tungsten film, is brought into contact with the above-described etching composition for a semiconductor substrate for a memory element to remove at least a part of the titanium-containing film.

### [Semiconductor Substrate]

The semiconductor substrate has a titanium-containing film that contains at least one of titanium and a titanium alloy and a metal tungsten film. The configuration of the semiconductor substrate is not particularly limited, and a publicly-known configuration can be suitably employed.

For example, when used for an embedded word line in a memory element, the semiconductor substrate may have a structure in which an insulating film, a barrier film made of titanium and/or a titanium alloy, and a metal tungsten film are layered in this order on a silicon substrate having a recess. In this regard, the barrier film and the metal tungsten film are usually arranged adjacent to each other.

### [Etching Composition for Semiconductor Substrate for Memory Element]

As the etching composition for a semiconductor substrate for a memory element, the above-described composition is used.

### [Contact]

The method of bringing the semiconductor substrate into contact with the etching composition for a semiconductor substrate for a memory element is not particularly limited, and a publicly-known technique can be suitably employed. Specifically, the semiconductor substrate may be immersed in the etching composition for a semiconductor substrate for a memory element, or the etching composition for a semiconductor substrate for a memory element may be sprayed onto the semiconductor substrate or dropped onto the semiconductor substrate (single wafer spin process or the like). In this regard, the immersion may be repeated two or more times, the spraying may be repeated two or more times, the dropping may be repeated two or more times, or the immersion, the spraying, and the dropping may be combined.

The contact temperature is not particularly limited, but it is preferably from 0 to 90° C., more preferably from 15 to 70° C., and even more preferably from 20 to 60° C.

The contact time is not particularly limited, but it is preferably from 10 seconds to 3 hours, more preferably from 30 seconds to 1 hour, even more preferably from 1 to 45 minutes, and particularly preferably from 1 to 5 minutes.

By bringing the semiconductor substrate into contact with the etching composition for a semiconductor substrate for a memory element, selective etching of titanium/a titanium alloy can be carried out.

### (Semiconductor Substrate for Memory Element)

The semiconductor substrate for a memory element obtained can be used for a memory element such as DRAM. This can realize size reduction and sophistication of the memory element.

### EXAMPLES

Hereinafter, the present invention will be specifically described by way of examples, but the present invention is not limited thereto.

### Example 1

Iodic acid (HIO₃) as the oxidizing agent (A), hydrogen fluoride (HF) as the fluorine compound (B), and benzethonium chloride (BZT) as the metal tungsten (W) corrosion inhibiter (C) were added to pure water, and the mixture was stirred to produce an etching composition for a semiconductor substrate for a memory element. In this regard, the addition ratios of iodic acid, hydrogen fluoride, and benzethonium chloride (BZT) were 0.018% by mass, 0.05% by mass, and 0.02% by mass, respectively, relative to the total mass of the etching composition for a semiconductor substrate for a memory element. Further, the pH and surface tension of the etching composition for a semiconductor substrate for a memory element were 2.4 and 38 mN/m, respectively. The pH of the etching composition for a semiconductor substrate for a memory element was measured at 23° C. using a tabletop PH meter (F-71) and a pH electrode (9615S-10D) manufactured by HORIBA, Ltd. Further, the surface tension of the etching composition for a semiconductor substrate for a memory element was measured at 23° C. using an automatic surface tensiometer DY-300 (manufactured by Kyowa Interface Science Co., Ltd.).

### Examples 2 to 17 and Comparative Example 1

Components to be added and the like were changed as shown in Table 1 below to produce etching compositions for a semiconductor substrate for a memory element. In each case, the pH and surface tension were measured by the same methods as those in Example 1.

TABLE 1

| | Oxidizing agent (A) | | Fluorine compound (B) | | W corrosion inhibiter (C) | | |
|---|---|---|---|---|---|---|---|
| | | Concentration | | Concentration | | Carbon number | Concentration |
| | Type | (% by mass) | Type*¹ | (% by mass) | Type*² | of side chain | (% by mass) |
| Example 1 | Iodic acid | 0.018 | HF | 0.05 | BZT | 17 | 0.02 |
| Example 2 | Iodic acid | 0.018 | HF | 0.05 | BOctDAC | 18 | 0.05 |
| Example 3 | Iodic acid | 0.018 | HF | 0.05 | BZT | 17 | 0.02 |
| Example 4 | Periodic acid | 0.002 | HF | 0.05 | BZT | 17 | 0.02 |
| Example 5 | Iodic acid | 0.018 | NH₄F HF | 0.143 | BZT | 17 | 0.02 |
| Example 6 | Iodic acid | 0.018 | H₂SiF₆ | 0.5 | BZT | 17 | 0.02 |
| Example 7 | Iodic acid | 0.018 | HF | 0.05 | BOctDAC | 18 | 0.05 |
| Example 8 | Iodic acid | 0.018 | HF | 0.05 | BZC | 8 to 18 | 0.05 |
| Example 9 | Iodic acid | 0.018 | HF | 0.05 | HexDMIC | 16 | 0.05 |
| Example 10 | Iodic acid | 0.018 | HF | 0.05 | OctDMIC | 18 | 0.05 |
| Example 11 | Iodic acid | 0.018 | HF | 0.05 | HexDPC | 16 | 0.05 |
| Example 12 | Iodic acid | 0.018 | HF | 0.05 | BTetDAC | 14 | 0.05 |
| Example 13 | Iodic acid | 0.018 | HF | 0.05 | BZT | 17 | 0.02 |
| Example 14 | Iodic acid | 0.018 | HF | 0.05 | BZT | 17 | 0.02 |
| Example 15 | Iodic acid | 0.018 | HF | 0.05 | BZT | 17 | 0.02 |
| Example 16 | Iodic acid | 0.018 | HF | 0.05 | BOctDAC | 18 | 0.05 |
| Example 17 | Iodic acid | 0.018 | HF | 0.05 | BOctDAC | 18 | 0.05 |
| Comparative | Iodic acid | 0.018 | HF | 0.05 | DPC | 12 | 0.005 |
| Example 1 | | | | | | | |

| | pH adjuster (D) | | | | | Surface |
|---|---|---|---|---|---|---|
| | | Concentration | Organic solvent (E) | | | tension |
| | Type*³ | (% by mass) | Type*⁴ | Concentration | pH | (mN/m) |
| Example 1 | — | 0 | — | 0 | 2.4 | 38 |
| Example 2 | — | 0 | — | 0 | 2.3 | 37 |
| Example 3 | Sulfuric acid | 0.5 | — | 0 | 1.3 | 34 |
| Example 4 | Sulfuric acid | 0.5 | — | 0 | 1.3 | 34 |
| Example 5 | Sulfuric acid | 0.5 | — | 0 | 1.4 | 33 |
| Example 6 | Sulfuric acid | 0.5 | — | 0 | 1.0 | 32 |
| Example 7 | Sulfuric acid | 0.5 | — | 0 | 1.2 | 35 |
| Example 8 | Sulfuric acid | 0.5 | — | 0 | 1.2 | 35 |
| Example 9 | Sulfuric acid | 0.5 | — | 0 | 1.1 | 37 |
| Example 10 | Sulfuric acid | 0.5 | — | 0 | 1.2 | 38 |
| Example 11 | Sulfuric acid | 0.5 | — | 0 | 1.2 | 38 |
| Example 12 | Sulfuric acid | 0.5 | — | 0 | 1.2 | 36 |
| Example 13 | MsOH | 0.5 | — | 0 | 1.3 | 38 |
| Example 14 | Hydrogen chloride | 0.5 | — | 0 | 1.0 | 32 |
| Example 15 | Sulfuric acid | 0.5 | EHexD | 1.5 | 1.3 | 30 |
| Example 16 | Sulfuric acid | 0.5 | HepOH | 0.1 | 1.3 | 29 |
| Example 17 | Sulfuric acid | 0.5 | EHexD | 1.5 | 1.3 | 32 |
| Comparative | Sulfuric acid | 0.5 | — | 0 | 1.3 | 57 |
| Example 1 | | | | | | |

*¹HF: hydrogen fluoride, NH₄F HF: ammonium acid fluoride, H₂SiF₆: hexafluorosilicic acid
*²BZT: benzethonium chloride, BOctDAC: benzyldimethyloctadecylammonium chloride, BZC: benzalkonium chloride, HexDMIC: 1-hexadecyl-3-methylimidazolium chloride, OctDMIC: 1-octadecyl-3-methylimidazolium chloride, HexDPC: 1-hexadecylpyridinium chloride, BTetDAC: benzyldimethyltetradecylammonium chloride monohydrate, DPC: dodecylpyridinium chloride
*³MsOH: methanesulfonic acid
*⁴EHexD: 2-ethylhexane-1,3-diol, HepOH: 1-heptanol

The structures of BZT, BOctDAC, BZC, HexDMIC, OctDMIC, HexDPC, BTetDAC, and DPC which were used as the metal tungsten corrosion inhibiter (C) in Examples 1 to 17 and Comparative Example 1 are shown below.

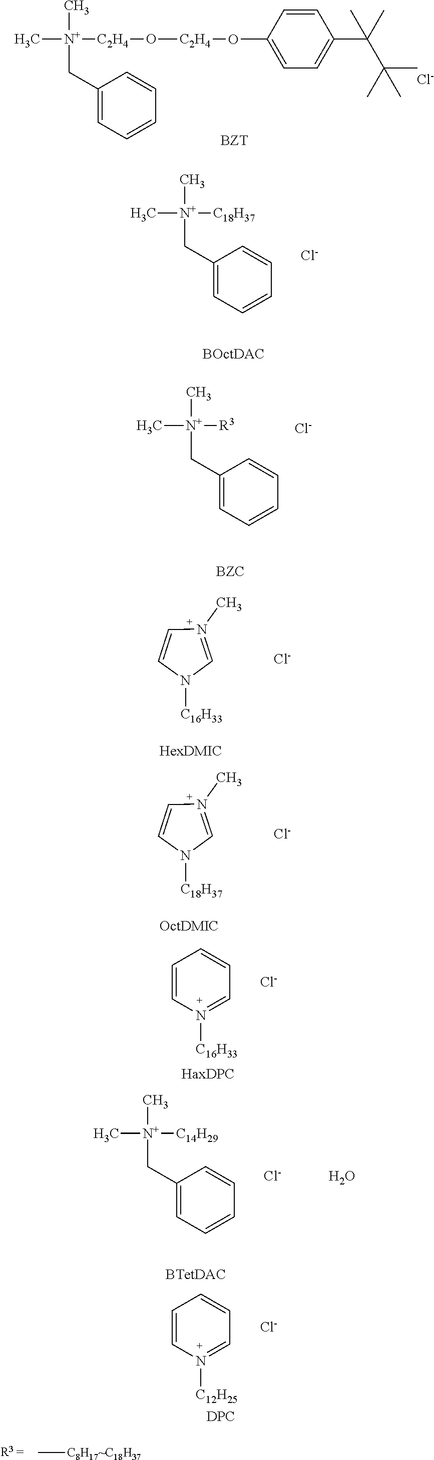

### [Evaluation]

Regarding the etching compositions for a semiconductor substrate for a memory element produced in Examples 1 to 17 and Comparative Example 1, the corrosion amount of the metal tungsten film, the etching amount of the titanium nitride film, the etching selectivity that is the ratio of the etching amount of the titanium nitride film to the corrosion amount of the metal tungsten film (TiN/W etching selectivity), and the etching rate of the thermally oxidized film (th-Ox) made of silicon dioxide were evaluated.

### (Preparation of Sample for Evaluation)

On a silicon substrate, a thermally oxidized film made of silicon dioxide (100 nm) was formed. On the surface of the thermally oxidized film, a titanium nitride film (5 nm), a metal tungsten film (50 nm), and a silicon dioxide film (50 nm) were sequentially formed by means of CVD (chemical vapor deposition) to prepare a wafer.

In the prepared wafer, a trench (groove) was formed from the side of the silicon dioxide film formed by CVD to reach the thermally oxidized film made of silicon dioxide on the surface of the silicon substrate, and thus a sample for evaluation (before etching) was prepared. Specifically, the prepared wafer was cut into a size of 1 cm×1 cm, and on a region for forming a trench (groove), a carbon protective film was formed in an FIB (focused ion beam) apparatus (Helios G4 UX (manufactured by Thermo scientific)). Next, by FIB, a trench (groove) was formed in the wafer from the surface of the carbon protective film. The obtained trench-processed body was treated with a dilute hydrofluoric acid solution (prepared by diluting 50% hydrogen fluoride 1000-fold (volume ratio) with water) at 70° C. for 5 minutes to prepare a sample for evaluation (before etching).

The schematic diagram of the prepared sample for evaluation (before etching) is shown in FIG. 2. A sample for evaluation (before etching) 40 has a thermally oxidized film 42 made of silicon dioxide (100 nm), a titanium nitride film 43 (5 nm), a metal tungsten film 44 (50 nm), a silicon dioxide film 45 (50 nm), and a carbon protective film 46 in this order on a silicon substrate 41. A trench (groove) has been formed by FIB via the carbon protective film 46 from the silicon dioxide film 45 to the thermally oxidized film 42 made of silicon dioxide. The formed trench (groove) has a trapezoidal shape, the width of the trench (groove) at the interface between the silicon dioxide film 45 and the metal tungsten film 44 is 40 nm, and the width of the trench (groove) at the interface between the titanium nitride film 43 and the thermally oxidized film 42 made of silicon dioxide is 20 nm.

### (Etching Treatment)

The sample for evaluation (before etching) was immersed in the etching composition for a semiconductor substrate for a memory element and it was allowed to stand at 50° C. for 30 minutes. The sample for evaluation was taken out from the etching composition for a semiconductor substrate for a memory element and subjected to FIB processing to obtain a sample for evaluation (after etching) having a smooth cross section.

### (Corrosion Amount of Metal Tungsten Film)

Using Helios G4 UX (manufactured by Thermo scientific), a TEM image of the sample for evaluation (after etching) was obtained.

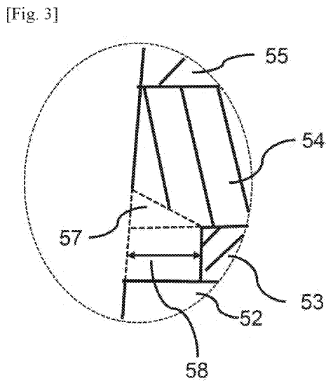

FIG. 3 is a schematic diagram of the sample for evaluation (after etching). In the sample for evaluation (after etching), a titanium nitride film 53 has been etched. Further, a metal tungsten film 54 may be etched (corroded).

The corrosion amount of the metal tungsten film was calculated based on the obtained TEM image using Image J (image processing software developed by Wayne Rasband, the National Institutes of Health, USA). Specifically, a metal tungsten film corroded region 57 (area) in FIG. 3 was quantified (unit: nm²). The obtained results are shown in Table 2 below.

### (Etching Amount of Titanium Nitride Film)

The etching amount of the titanium nitride film was calculated based on the TEM image obtained for calculating the corrosion amount of the metal tungsten film, using Image J (image processing software developed by Wayne Rasband, the National Institutes of Health, USA). Specifically, an etching depth 58 of the titanium nitride film in FIG. 3 was quantified (unit: nm). By multiplying the etching depth (unit: nm) of the titanium nitride film by the area (5 nm: see FIG. 2) of the titanium nitride film in contact with the etching composition for a semiconductor substrate for a memory element, the etching amount of the titanium nitride film was calculated (unit: nm²). The obtained results are shown in Table 2 below.

### (Calculation of TiN/W Etching Selectivity)

By dividing the etching amount (nm²) of the titanium nitride film by the corrosion amount (nm²) of the metal tungsten film, the TiN/W etching selectivity was calculated. The obtained results are shown in Table 2 below.

### (Etching Rate of Thermally Oxidized Film (Th-Ox) Made of Silicon Dioxide)

Using an optical film thickness gauge n&k 1280 (manufactured by n&k Technology Inc.), the film thickness of the thermally oxidized film (th-Ox) made of silicon dioxide of the sample for evaluation (before etching) and the film thickness of the thermally oxidized film (th-Ox) made of silicon dioxide of the sample for evaluation (after etching) were measured. By dividing the film thickness difference before and after the etching treatment by the treatment time (30 minutes), the etching rate of the thermally oxidized film (th-Ox) made of silicon dioxide was calculated. The obtained results are shown in Table 2 below.

TABLE 2

| | Corrosion | Etching amount | TiN/W | Etching rate |
|---|---|---|---|---|
| | amount of W | of TiN | etching | of th-Ox |
| | (nm²) | (nm²) | selectivity | (Å/min) |
| Example 1 | 357 | 345 | 0.97 | 1.7 |
| Example 2 | 379 | 195 | 0.51 | 8.8 |
| Example 3 | 253 | 260 | 1.03 | 0.5 |
| Example 4 | 199 | 245 | 1.23 | 1.2 |
| Example 5 | 290 | 370 | 1.28 | 4.6 |
| Example 6 | 184 | 240 | 1.30 | 0.8 |
| Example 7 | 363 | 290 | 0.80 | 1.0 |
| Example 8 | 303 | 265 | 0.87 | 0.9 |
| Example 9 | 305 | 205 | 0.67 | 1.0 |
| Example 10 | 321 | 225 | 0.70 | 1.2 |
| Example 11 | 313 | 220 | 0.70 | 1.2 |
| Example 12 | 367 | 280 | 0.76 | 0.6 |
| Example 13 | 124 | 225 | 1.81 | 0.9 |
| Example 14 | 188 | 220 | 1.17 | 1.0 |
| Example 15 | 104 | 225 | 2.16 | 0.5 |
| Example 16 | 334 | 250 | 0.75 | 1.2 |
| Example 17 | 342 | 210 | 0.61 | 0.4 |
| Comparative | 463 | 355 | 0.77 | 0.8 |
| Example 1 | | | | |

It is understood from the results in Table 2 that the amount of the metal tungsten film corroded by each etching composition for a semiconductor substrate for a memory element in Examples 1 to 17 is small. As a result, it is considered that semiconductor substrates for a memory element obtained exhibit improved performance.

### EXPLANATIONS OF LETTERS OR NUMERALS

10 semiconductor substrate (before etching)
11, 21, 31 silicon substrate having recess
12, 22, 32 insulating film
13 barrier film (before etching)
14 metal tungsten film
20, 30 semiconductor substrate (after etching)
23, 33 barrier film (after etching)
24, 34 metal tungsten film
24a metal tungsten film surface
24b metal tungsten film side surface
34c metal tungsten film corroded surface
40 sample for evaluation (before etching)
41 silicon substrate
42 thermally oxidized film made of silicon dioxide
43 titanium nitride film (before etching)
44 metal tungsten film
45 silicon dioxide film
46 carbon protective film
52 thermally oxidized film made of silicon dioxide
53 titanium nitride film (after etching)
54 metal tungsten film
55 silicon dioxide film
57 metal tungsten film corroded region
58 etching depth of titanium nitride film

1. An etching composition for a semiconductor substrate for a memory element, comprising an oxidizing agent (A), a fluorine compound (B), and a metal tungsten corrosion inhibiter (C),
wherein the metal tungsten corrosion inhibiter (C) contains at least one selected from the group consisting of an ammonium salt represented by formula (1) and a heteroaryl salt having a substituted or unsubstituted alkyl group having 14 to 30 carbon atoms: 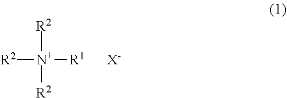
wherein in formula (1):
R¹ represents a substituted or unsubstituted alkyl group having 14 to 30 carbon atoms, a substituted or unsubstituted alkyl(poly)heteroalkylene group having 14 to 30 carbon atoms, or a substituted or unsubstituted aryl(poly)heteroalkylene group having 14 to 30 carbon atoms;
each R² independently represents a substituted or unsubstituted alkyl group having 1 to 30 carbon atoms, or a substituted or unsubstituted aryl group having 6 to 30 carbon atoms; and
X⁻ represents a halide ion, a hydroxide ion, an organic sulfonate ion, a tetrafluoroborate anion, or a hexafluorophosphate anion.

2. The etching composition for a semiconductor substrate for a memory element according to claim 1, wherein said R¹ represents a substituted or unsubstituted alkyl(poly)heteroalkylene group having 14 to 30 carbon atoms, or a substituted or unsubstituted aryl(poly)heteroalkylene group having 14 to 30 carbon atoms.

3. The etching composition for a semiconductor substrate for a memory element according to claim 2, wherein said R¹ represents a substituted or unsubstituted aryl(poly)heteroalkylene group having 14 to 20 carbon atoms.

4. The etching composition for a semiconductor substrate for a memory element according to claim 1, which has a surface tension of 50 mN/m or less.

5. The etching composition for a semiconductor substrate for a memory element according to claim 1, which further comprises a pH adjuster (D).

6. The etching composition for a semiconductor substrate for a memory element according to claim 1, which has a pH ranging from 0.1 to 5.0.

7. The etching composition for a semiconductor substrate for a memory element according to claim 1, which further comprises an organic solvent (E).

8. The etching composition for a semiconductor substrate for a memory element according to claim 7, wherein the organic solvent (E) is an alcohol.

9. A method for producing a semiconductor substrate for a memory element, comprising a step in which a semiconductor substrate, which has a titanium-containing film that contains at least one of titanium and a titanium alloy and a metal tungsten film, is brought into contact with the etching composition for a semiconductor substrate for a memory element according to claim 1 to remove at least a part of the titanium-containing film.
